(19) United States
(12) Patent Application Publication
(10) Pub. No.: US 2022/0254912 A1
(43) Pub. Date: Aug. 11, 2022

(54) AN ENHANCEMENT MODE METAL INSULATOR SEMICONDUCTOR HIGH ELECTRON MOBILITY TRANSISTOR

(71) Applicant: POWER INTEGRATIONS, Inc., SAN JOSE, CA (US)

(72) Inventor: JAMAL RAMDANI, LAMBERTVILLE, NJ (US)

(73) Assignee: POWER INTEGRATIONS, Inc., SAN JOSE, CA (US)

(21) Appl. No.: 17/610,946

(22) PCT Filed: May 23, 2019
(86) PCT No.: PCT/US2019/033741

§ 371 Date: Nov. 12, 2021

(51) Int. Cl. H01L 29/778; H01L 29/20; H01L 29/66; H01L 29/45; H01L 21/04; H01L 29/51

(52) U.S. Cl. CPC H01L 29/7786; H01L 29/2003; H01L 29/513; H01L 29/452; H01L 21/0485; H01L 29/66462

(57) ABSTRACT

An enhancement mode metal insulator semiconductor high electron mobility transistor (HEMT) is presented herein. By using a polarization stack to replace the traditional barrier layer, a thinner barrier layer (e.g., a thinner layer of AlGaN) may be formed during fabrication to effectuate a low-sheet-resistance two-dimensional electron gas. Advantageously, the thinner (.i.e., less-than-ten nanometers) barrier layer mitigates reactive ion etching (RIE) induced surface damage. This in turn allows the formation of a recessed gate. Additionally, a dual dielectric gate stack may be deposited to further reduce leakage currents and to improve subthreshold slope.

### FIELD OF THE DISCLOSURE

The present invention relates to the fabrication of a high electron mobility transistor (HEMT) and more particularly to a gallium nitride (GaN) based enhancement mode metal insulator semiconductor field effect transistor.

### BACKGROUND INFORMATION

Gallium nitride (GaN) and other wide band-gap nitride III based direct transitional semiconductor materials exhibit high break-down electric fields and avail high current densities. In this regard GaN based semiconductor devices are actively researched as an alternative to silicon based semiconductor devices in power and high frequency applications. For instance, a GaN HEMT may provide lower specific on resistance with higher breakdown voltage relative to a silicon power field effect transistor of commensurate area.

Power field effect transistors (FETs) can be enhancement mode or depletion mode. An enhancement mode device may refer to a transistor (e.g., a field effect transistor) which blocks current (i.e., which is off) when there is no applied gate bias (i.e., when the gate to source bias is zero). In contrast, a depletion mode device may refer to a transistor which allows current (i.e., which is on) when the gate to source bias is zero.

Additionally, the specific on resistance of a power device (e.g., a power FET) may refer to a resistance multiplied by device area. In this way specific on resistance offers a figure of merit relating to how much semiconductor area may be required to realize a desired value of on resistance.

### BRIEF DESCRIPTION OF THE DRAWINGS

Non-limiting and non-exhaustive embodiments for an enhancement mode metal insulator semiconductor high electron mobility transistor (HEMT) are described with reference to the following figures, wherein like reference numerals refer to like parts throughout the various views unless otherwise specified.

FIG. 1A illustrates a first device cross section during the fabrication of an enhancement mode metal insulator semiconductor HEMT according to the teachings herein.

FIG. 1B illustrates a second device cross section during the fabrication of the enhancement mode metal insulator semiconductor HEMT according to the teachings herein.

FIG. 1C illustrates a third device cross section during the fabrication of the enhancement mode metal insulator semiconductor HEMT according to the teachings herein.

FIG. 1D illustrates a fourth device cross section during the fabrication of the enhancement mode metal insulator semiconductor HEMT of FIG. 1C.

FIG. 1E illustrates a fifth device cross showing the enhancement mode metal insulator semiconductor HEMT of FIG. 1C.

FIG. 2A illustrates a process flow for fabricating an enhancement mode metal insulator semiconductor HEMT according to a first embodiment.

FIG. 2B illustrates a process flow for fabricating an enhancement mode metal insulator semiconductor HEMT according to a second embodiment.

FIG. 2C illustrates a process flow for forming a polarization stack according to an embodiment.

FIG. 2D illustrates a process flow for forming a recessed gate according to an embodiment.

FIG. 2E illustrates a process flow for depositing a dual dielectric according to an embodiment.

FIG. 3 illustrates transfer characteristics of drain-to-source current versus gate-to-source voltage for a HEMT fabricated according to the teachings herein

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements and layers in the figures may be exaggerated relative to other elements to help to improve understanding of various embodiments of the teachings herein. Also, common but well-understood elements, layers, and/or process steps that are useful or necessary in a commercially feasible embodiment are often not depicted in order to facilitate a less obstructed view of these various embodiments of an enhancement mode metal insulator semiconductor HEMT.

### DETAILED DESCRIPTION

In the following description, numerous specific details are set forth in order to provide a thorough understanding of an enhancement mode metal insulator semiconductor HEMT. It will be apparent, however, to one having ordinary skill in the art that the specific detail need not be employed to practice the teachings herein. In other instances, well-known materials or methods have not been described in detail in order to avoid obscuring the present disclosure.

Reference throughout this specification to “one embodiment”, “an embodiment”, “one example” or “an example” means that a particular feature, structure, method, process, and/or characteristic described in connection with the embodiment or example is included in at least one embodiment of an enhancement mode metal insulator semiconductor HEMT. Thus, appearances of the phrases “in one embodiment”, “in an embodiment”, “one example” or “an example” in various places throughout this specification are not necessarily all referring to the same embodiment or example. Furthermore, the particular features, structures, methods, processes and/or characteristics may be combined in any suitable combinations and/or subcombinations in one or more embodiments or examples. In addition, it is appreciated that the figures provided herewith are for explanation purposes to persons ordinarily skilled in the art and that the drawings are not necessarily drawn to scale.

In the context of the present application, when a transistor is in an “off-state” or “off” the transistor blocks current and/or does not substantially conduct current. Conversely, when a transistor is in an “on-state” or “on” the transistor is able to substantially conduct current. By way of example, a transistor may comprise an N-channel metal-oxide-semiconductor (NMOS) field-effect transistor (FET) with the high-voltage being supported between the first terminal, a drain, and the second terminal, a source.

Also, throughout this specification, several terms of art are used. These terms are to take on their ordinary meaning in the art from which they come, unless specifically defined herein or the context of their use would clearly suggest otherwise. For instance, one of ordinary skill in the art may recognize and distinguish sheet resistance (i.e., sheet rho) from resistivity. Additionally, it should be noted that element names and symbols may be used interchangeably throughout this document (e.g., Si vs. silicon); however, both have identical meanings.

As discussed above an enhancement mode device may refer to a transistor which blocks current when a control voltage (e.g., a gate-to-source voltage) is low (e.g., zero volts). In many circuit and switching applications, it may be desirable to use an enhancement mode transistor (i.e., an enhancement mode device) to realize circuit functions. For instance, in power applications it is often desirable to use a power transistor as a switch (i.e., a power switch). Ideally, a power transistor may operate as a switch when it blocks current in one state (e.g., a state of zero control voltage) and provides current with low on resistance and low power loss in a second state (e.g., a state of non-zero control voltage).

Also, as discussed above, GaN based HEMTs (i.e., GaN HEMTs) may provide lower specific on resistance with higher breakdown voltage relative to a silicon power field effect transistor of commensurate area. Thus, a GaN HEMT may be a desirable replacement for a silicon power FET.

One aspect of a GaN HEMT is the formation of a two-dimensional electron gas between a GaN layer and a barrier layer. The barrier layer may be a material such as aluminum gallium nitride (AlGaN) having a wider bandgap than that of the GaN layer; and one reason for the formation of the two-dimensional electron gas can be explained by solid state physics: a diffusive contact potential exists (i.e., the contact potential) between the barrier layer (e.g., the AlGaN layer) and the GaN layer. Another reason for the formation may be related to a polarization induced charge due to crystal asymmetry.

Research has shown that present state-of-the-art GaN HEMTs may necessitate a barrier layer (e.g. a barrier layer of AlGaN) of thickness greater than ten nanometers in order to realize a low-loss low-on-resistance power device. Using a barrier layer with a thickness of greater than ten nanometers may allow for the formation of the two-dimensional electron gas with sufficiently low sheet resistance for power device applications.

Present state of the art enhancement mode GaN HEMTs include p-GaN HEMTs and recessed gate metal insulator semiconductor HEMTs (MISHEMTs). A p-GaN HEMT may be fabricated by providing a p-GaN layer (i.e., a p-type layer) in the gate region so as to shift the threshold voltage. A recessed gate MISHEMT removes (i.e., recesses) a barrier layer of aluminum gallium nitride (AlGaN) to prevent the formation of the two-dimensional electron gas in a recessed gate region.

Unfortunately, the p-GaN HEMT and the recessed gate MISHEMT suffer from relatively high sheet resistance compared to that of a depletion mode GaN HEMT. Moreover, fabrication of the recessed gate MISHEMT may necessitate reactive ion etching (RIE) through at least ten nanometers of the requisite barrier layer (e.g., through an AlGaN layer of at least ten nanometers) in order to expose the GaN surface in the gate region. The prolonged exposure during the RIE can cause surface damage and lead to unreliable device behavior. For instance, the surface damage may lead to high leakage currents and to poor subthreshold slope characteristics.

Accordingly, there is a need for an improved enhancement mode HEMT and enhancement mode HEMT process to overcome the deficiencies of the p-GaN HEMT and the recessed gate MISHEMT.

An enhancement mode metal insulator semiconductor high electron mobility transistor (HEMT) is presented herein. By using a polarization stack to replace the traditional barrier layer, a thinner barrier layer (e.g., a thinner layer of AlGaN) may be formed during fabrication to effectuate a low-sheet-resistance two-dimensional electron gas. Advantageously, the thinner (i.e., less than ten nanometers) barrier layer mitigates reactive ion etching (RIE) induced surface damage. This in turn allows the formation of a recessed gate. Additionally, a dual dielectric gate stack may be deposited to further reduce leakage currents and to improve subthreshold slope.

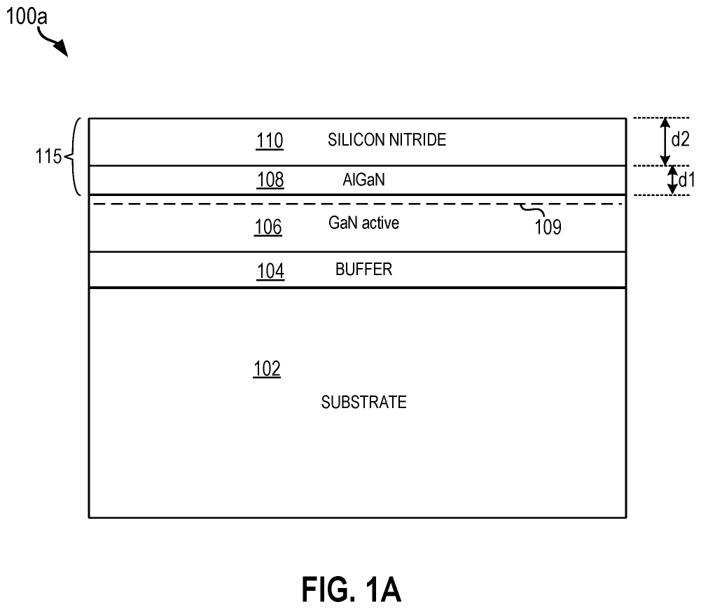

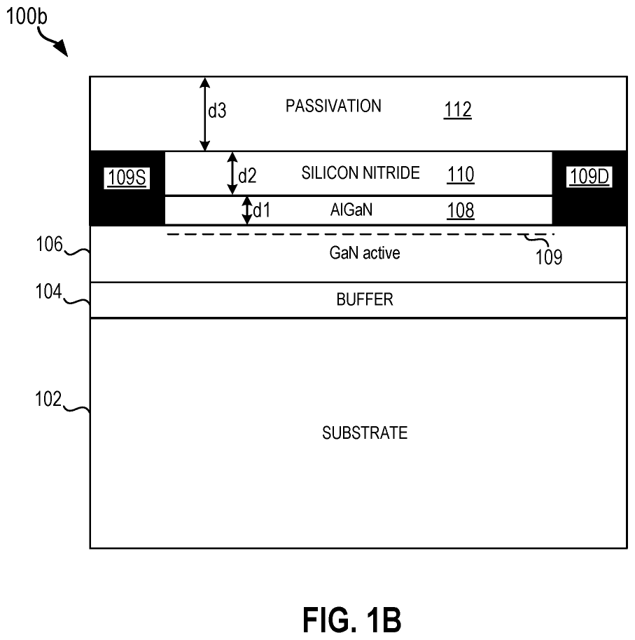

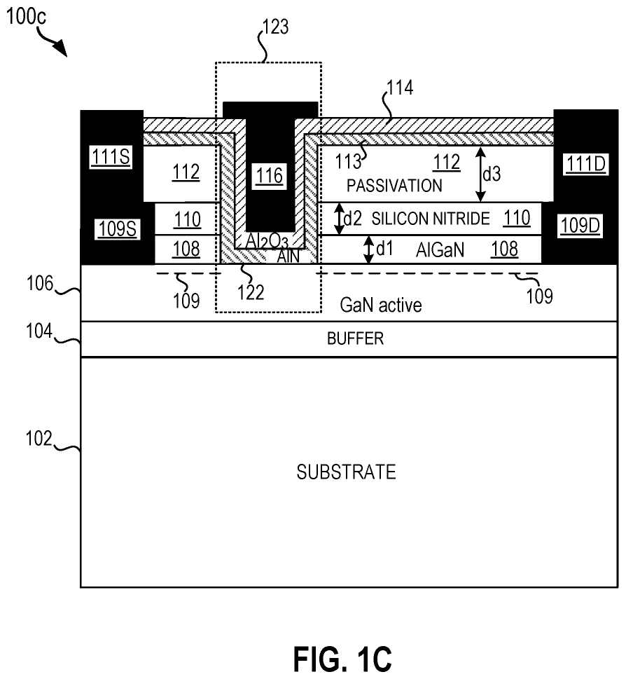

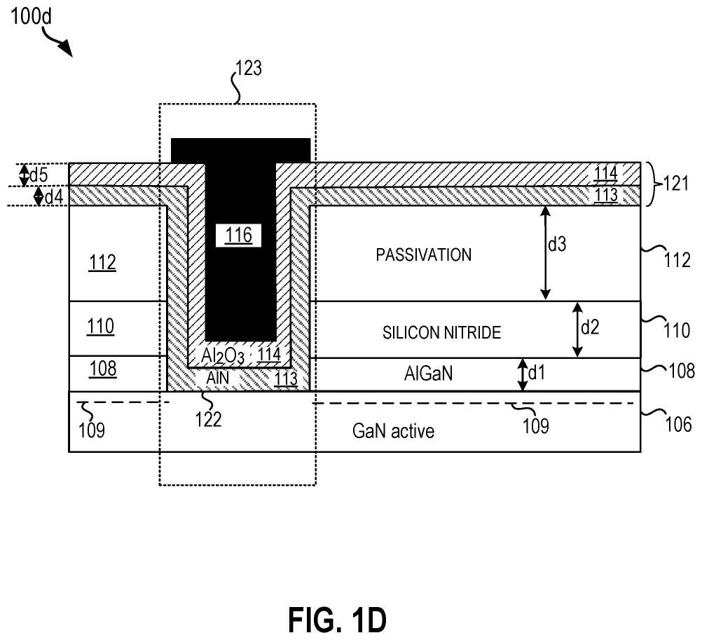

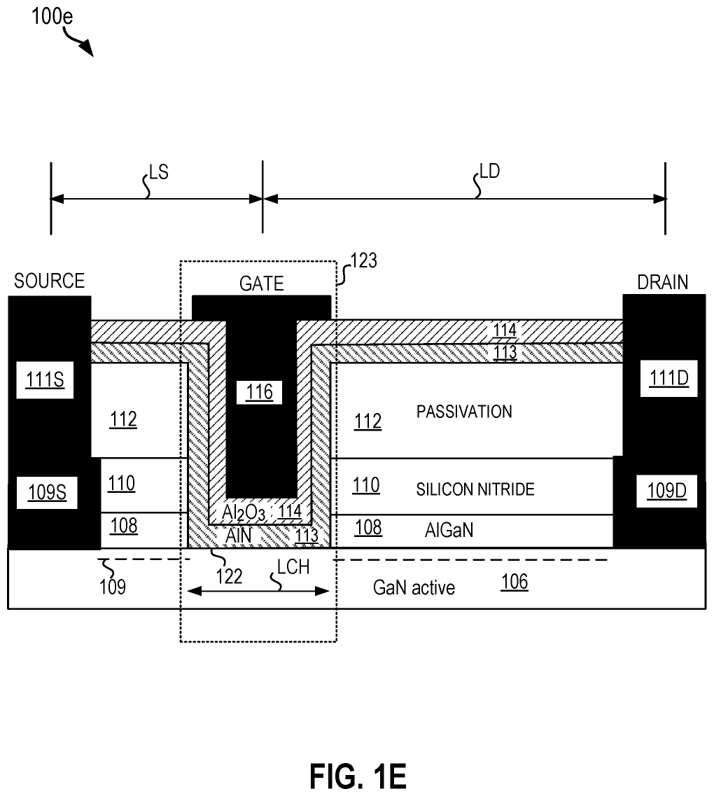

FIG. 1A illustrates a first device cross section 100a during the fabrication of an enhancement mode metal insulator semiconductor HEMT according to the teachings herein. The first device cross section 100a depicts a substrate 102, a buffer layer 104, a gallium nitride (GaN) active layer 106, and a polarization stack 115. The polarization stack 115 includes an aluminum gallium nitride (AlGaN) barrier layer 108 and a silicon nitride layer 110.

Materials available for the substrate 102 may include, but are not limited to, GaN, sapphire, silicon carbide (SiC), and silicon (Si). The selection of a material for substrate 102 may depend, in part, upon material cost, material availability, lattice mismatch with GaN, and/or thermal conductivity. The buffer layer 104 may be grown on the substrate 102 to mitigate some of the problems (e.g., dislocations and cracks) associated with material mismatch (e.g., lattice mismatch). For instance, the substrate 102 can comprise <111> Si (i.e., a Silicon wafer with crystal orientation <111>), and the buffer layer 104 may be a layer comprising GaN, AlGaN, and/or aluminum nitride (AlN) to buffer and to improve the material quality between the subsequent GaN active layer 106 and the substrate 102. Additionally, one or more of the buffer layer 104 and the GaN active layer 106 may be grown, starting from the substrate 102, using an epitaxial process such as metal organic chemical vapor deposition (MOCVD).

The polarization stack 115 may be an epitaxial film which comprises the AlGaN barrier layer 108 of thickness d1 and the silicon nitride layer 110 of thickness d2. The epitaxial film may be adjusted so that the AlGaN barrier layer 108 has a thickness d1 less than a state-of-the-art value (e.g., less than ten nanometers). The AlGaN barrier layer 108 may, for instance, be grown using a controlled epitaxial growth rate (e.g., a rate of 200 nanometers per hour) to have a layer thickness d1 between four nanometers and six nanometers. The silicon nitride layer 110 may be formed (e.g., grown) on the AlGaN barrier layer 108 so that the combination (i.e., the polarization stack 115) leads to the formation of a low-sheet-resistance two-dimensional electron gas 109 at the interface between the AlGaN barrier layer 108 and the GaN active layer 106. For instance, the silicon nitride layer 110 may be grown in-situ, following the growth of the AlGaN barrier layer 108, to have a thickness d2 (e.g., forty nanometers) suitable for effectuating piezoelectric polarization between the AlGaN barrier layer 108 and the GaN active layer 106. Piezoelectric polarization may advantageously effectuate the low-sheet-resistance two-dimensional electron gas 109. Additionally, as will be discussed below with regards to FIG. 1C, the AlGaN barrier layer 108 has a thickness d1 which may advantageously mitigate reactive ion etching (RIE) induced surface damage (see, e.g., surface interface 122 of FIG. 1C).

FIG. 1B illustrates a second device cross section 100b during the fabrication of the enhancement mode metal insulator semiconductor HEMT according to the teachings herein. The second device cross section 100b illustrates additional layers following the formation of a source Ohmic contact 109S, a drain Ohmic contact 109D, and a passivation layer 112. The source Ohmic contact 109S and drain Ohmic contact 109D may be formed using a multilayer alloy such as a titanium, aluminum, titanium-nitride, aluminum-copper (Ti/Al/TiN/AlCu) multilayer. Subsequently, the passivation layer 112 of thickness d3 (e.g., one hundred and fifty nanometers) may be formed using plasma enhanced chemical vapor deposition (PECVD). In one embodiment the passivation layer 112 can comprise silicon nitride which may advantageously enhance the underlying polarization stack 115. For instance when the passivation layer 112 is a PECVD silicon nitride layer, then the passivation layer 112 may enhance (e.g., increase) piezoelectric polarization above that due to the silicon nitride layer 110. In response the sheet resistance of the two dimensional electron gas 109 may advantageously decrease (i.e., improve).

FIG. 1C illustrates a third device cross section 100c during the fabrication of the enhancement mode metal insulator semiconductor HEMT according to the teachings herein. The third device cross section 100c illustrates additional layers following the formation of a recessed gate region 123, source metal layer 111S, and drain metal layer 111D. The source and drain metal layers 111S, 111D may comprise an alloy including, but not limited to, aluminum and/or titanium to form low resistance electrical connections with the source and drain Ohmic contacts 109S, 109D, respectively.

Additionally, the third device cross section 100c shows an aluminum nitride (AlN) layer 113 and an aluminum oxide layer (Al₂O₃) layer 114. In forming the recessed gate region 123, the AlN layer 113 may advantageously improve device characteristics (e.g., may reduce interface traps) by reducing dangling bonds at the surface interface 122 between the GaN nitride layer 106 and the AlN layer 113. As will be further described below with respect to FIG. 1D, the subsequent aluminum oxide layer 114 may advantageously provide a gate dielectric suitable for enhancement mode operation.

FIG. 1D illustrates a fourth device cross section 100d during the fabrication of the enhancement mode metal insulator semiconductor HEMT of FIG. 1C. The fourth device cross section 100d illustrates the recessed gate region 123 of the third device cross section 100c and further delineates a dual dielectric 121. Neighboring layers and device regions, including the source metal layer 111S, drain metal layer 111D, source Ohmic contact 109S, drain Ohmic contact 109D, buffer layer 104, and substrate 102, have been excluded from the fourth device cross section 100d in order to facilitate discussion of the recessed gate region 123 and the dual dielectric 121.

The recessed gate region 123 includes the dual dielectric 121, the surface interface 122, and a gate contact 116. In some embodiments the gate contact 116 may be deposited at the same time as the source metal layer 111S and drain metal layer 111D; additionally the gate contact 116 may be a metal alloy comprising aluminum and/or titanium.

During operation, the gate contact 116 may receive a gate voltage (e.g., a gate-to-source voltage) which may control a drain-to-source current between the drain metal layer 111D and the source metal layer 111S. Under zero gate voltage conditions and/or equilibrium conditions, the recessed gate region 123 may lead to the depletion (i.e., the removal) of the two dimensional electron gas 109 in the vicinity of the surface interface 122. In this way the recessed gate region 123 may be configured to block current flow (i.e., a drain-to-source current) when the gate voltage (e.g., gate-to-source voltage) is zero. As further illustration of this concept, FIG. 1D shows the depletion (e.g., the lack) of the two-dimensional electron gas 109 in the vicinity of the surface interface 122.

Also, as shown in FIG. 1D, the dual dielectric 121 may comprise the AlN layer 113 and the aluminum oxide layer 114. The AlN layer 113 can have a thickness d4 (e.g., four to eight nanometers) suitable for creating a low defect surface interface 122 by reducing interface traps and surface states at the surface interface 122. The aluminum oxide layer 114 may have a thickness d5 (e.g., five to fifteen nanometers) with a dielectric strength (e.g., ten to twelve megavolts per centimeter) suitable for reliably sustaining gate voltages of at least three volts. Accordingly, the dual dielectric 121 may function as an “insulator” between the gate contact 116 (e.g., the metal) and the GaN active layer 106 (e.g., the semiconductor); and the dual dielectric 121 may have a total thickness (e.g., a total thickness d4 plus d5) such that the metal insulator semiconductor HEMT operates in enhancement mode.

FIG. 1E illustrates a fifth device cross 100e showing the enhancement mode metal insulator semiconductor HEMT of FIG. 1C. The fifth device cross section 100e is similar to the fourth device cross section 100d except it depicts the formation of a source, gate, and drain by source metal layer 111S, the gate contact 116, and the drain metal layer 111D. Additionally, the fifth device cross section 100e illustrates a channel length LCH, a source-to-gate contact length LS, and a drain-to-gate contact length LD. According to semiconductor device physics, an “on” and “off” state of an enhancement mode metal insulator semiconductor HEMT may depend on parameters including the channel length LCH (e.g., two microns), the source-to-gate contact length LS, and the drain-to-gate contact length LD. As one of ordinary skill in the art may appreciate, values of the channel length LCH, the source-to-gate contact length LS, and the drain-to-gate contact length LD may be determined, at least in part, by lithography (i.e., critical dimensions) and also by desired electrical properties (e.g., a drain-to-source breakdown voltage).

Accordingly, the device structure depicted by cross section 100e, and also by cross sections 100a-d, should not be considered limiting. For instance, the cross section 100e may depict part of a unit cell which may be repeated for the manufacture of a power device. As one of ordinary skill in the art may appreciate, the cross section 100e can have a pitch and an associated “cell” area which may determine, in part, a specific on-resistance of a power device. Moreover, the cross section 100e, and cross sections 100a-d, can have greater or fewer layers. For instance, there can be additional passivation and/or metallization layers (e.g., field plates).

Characterization of a metal insulator semiconductor HEMT formed according to the cross sections 100a-e may include the measurement of device characteristics. Device characteristics may include, but are not limited to, transfer relationships such as drain-to-source current as a function of a gate voltage. Reliability parameters may also be measured in order to classify device robustness and stability (e.g., repeatability) as a function of time and temperature. For instance, a measure of device robustness can include a time-dependent dielectric breakdown (TDDB).

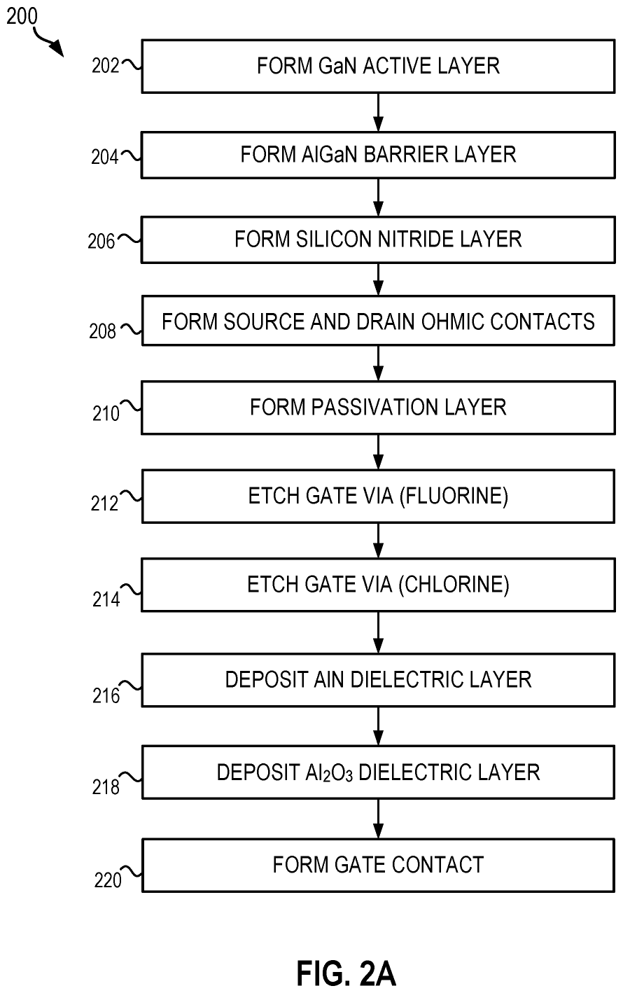

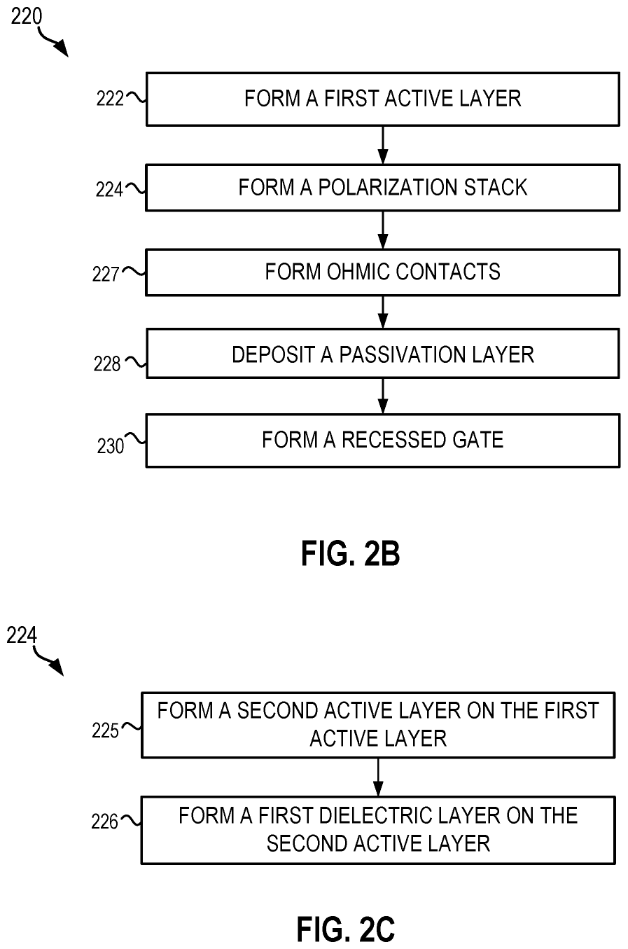

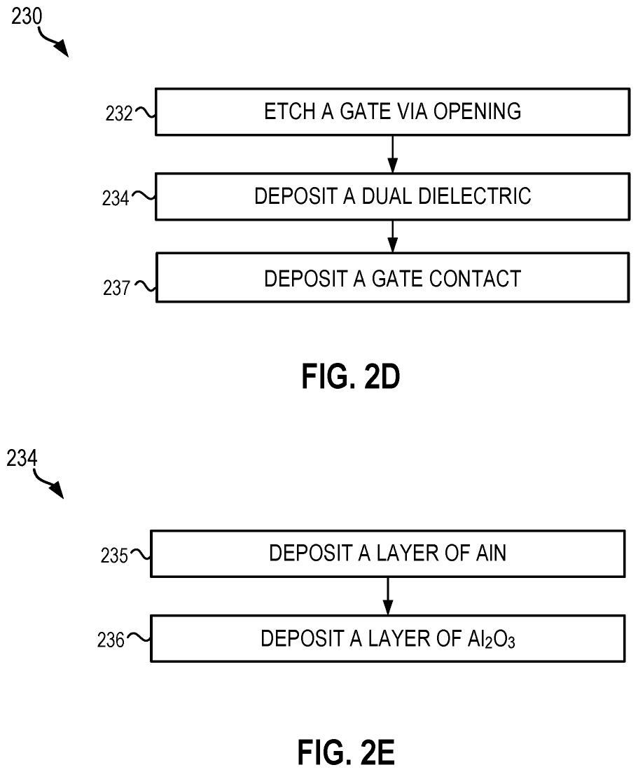

As discussed above, the recessed gate region 123 and the gate contact 116 (i.e., gate) may function as a control terminal configured to receive a gate voltage. During device operation the gate voltage may be applied to the gate contact 116 to modulate a channel in the vicinity of the surface interface 122; in this way the gate voltage may control a drain-to-source current between the drain (i.e., drain metal layer 111D) and the source (i.e., source metal layer 111S). As discussed below in the description of FIG. 2A through FIG. 2E, the process steps for fabricating an enhancement mode metal insulator semiconductor HEMT (e.g., as depicted by the first-fifth cross sections 100a-e) may avail device characteristics (e.g., specific on-resistance) commensurate with that of a depletion-mode (i.e., normally “on”) metal insulator semiconductor HEMT.

FIG. 2A illustrates a process flow 200 for fabricating an enhancement mode metal insulator semiconductor HEMT according to a first embodiment. Step 202 may correspond to forming a GaN active layer 106 by growing GaN. For instance, the GaN active layer 106 may be grown using chemical vapor deposition (CVD) epitaxy, also referred to as metal organic chemical vapor deposition (MOCVD). Alternatively, the GaN active layer 106 may be grown using molecular beam epitaxy (MBE). In some embodiments the GaN active layer 106 may be formed to have a thickness between one micron and five microns.

Step 204 may correspond to forming an AlGaN barrier layer 108 of thickness d1 on the GaN active layer 106. The AlGaN barrier layer 108 may also be referred to as an active layer, and according to the teachings herein, the AlGaN barrier layer 106 may be grown to have a thickness d1 less than traditional state-of-the-art thickness (e.g., less than ten nanometers). For instance, in step 204 the AlGaN barrier layer 108 may be grown using MOCVD and/or MBE such that the layer thickness d1 is between four nanometers and six nanometers (e.g., five nanometers). According to compound semiconductor fabrication principles, a layer thickness between four nanometers and six nanometers may hinder the formation of a low-sheet-resistance two-dimensional electron gas and/or elevate sheet resistance to unsuitable values (e.g., values greater than one-thousand Ohms-per-square). According to the teachings herein, the next step 206 may mitigate the above problem of high sheet resistance by forming a silicon nitride layer 110 with thickness d2 (e.g., forty nanometers).

In step 206 the silicon nitride layer 110 may also be deposited using MOCVD. For instance, the silicon nitride layer 110 may be deposited in-situ following step 204. Alternatively, the silicon nitride layer 110 may be deposited ex-situ. The combination of steps 204 and 206 may lead to the formation of the polarization stack 115, which may avail the formation of a low-sheet-resistance two-dimensional electron gas 109 by virtue of piezoelectric polarization. For instance, experimental data indicates that a polarization stack 115, as formed by steps 204 and 206 may lead to the formation of a two-dimensional electron gas 109 having a sheet-rho (i.e., a sheet resistance) of approximately six hundred Ohms-per-square.

In one embodiment, step 206 may be performed until a target value of sheet resistance is measured. For instance, during the growth of the silicon nitride layer 110 in step 206, the sheet resistance due the two-dimensional electron gas 109 may be measured in-situ; then upon reaching a target sheet-resistance value (e.g., six hundred Ohms-per-square), step 206 may be concluded.

Alternatively, experimental data based on a design-of-experiments, varying thickness d1 and thickness d2, may be used to determine a process recipe for steps 204 and 206. For instance, experimental data of sheet resistance of the two-dimensional electron gas 109 versus layer thickness may be used to provide guidance on target thickness values (i.e., target values of thickness d1 and thickness d2). Experiments may indicate a process recipe whereby during step 204 the AlGaN barrier layer 108 is grown to have a thickness d1 equal to five nanometers plus or minus a tolerance; additionally, during step 204 the recipe may indicate a step 204 target sheet resistance (i.e., a two dimensional electron gas sheet resistance) between one-thousand two-hundred Ohms-per-square to one-thousand five-hundred Ohms-per-square. Next, during step 206 the process recipe may be tailored such that the silicon nitride layer 110 is deposited in-situ to a thickness d2 (e.g., forty nanometers plus or minus a tolerance) such that a step 206 target sheet resistance reduces to six-hundred Ohms-per-square plus or minus a tolerance.

In the next step 208, the source and drain Ohmic contacts 109S, 109D may be formed. For instance, as discussed above, the source Ohmic contact 109S and the drain Ohmic contact 109D may be formed using a multilayer alloy such as a titanium, aluminum, titanium-nitride, aluminum-copper (Ti/Al/TiN/AlCu) multilayer.

In step 210, a passivation layer 112 of thickness d3 is formed. The passivation layer 112 can be a silicon nitride passivation layer deposited using a plasma enhanced chemical vapor deposition (PECVD) process recipe. Using a passivation layer 112 comprising silicon nitride may advantageously improve sheet resistance of the two-dimensional electron gas 109. For instance, according to experimental data, when the passivation layer 112 comprises silicon nitride and has a thickness of one hundred and fifty nanometers, the sheet resistance may advantageously decrease from its initial value (e.g., six hundred Ohms-per-square) to an improved value (e.g., between four hundred Ohms-per-square and five hundred Ohms-per-square). As one of ordinary skill in the art may appreciate, a value of less than five hundred Ohms-per-square may be commensurate with a sheet resistance measured on a depletion-mode metal insulator semiconductor HEMT.

Subsequent steps 212 and 214 may correspond to etching steps relating to the etching of a gate via (i.e., the recessed gate region 123). When the passivation layer 112 comprises silicon nitride, step 212 may refer to using a RIE process to etch silicon nitride (i.e., passivation layer 112 and silicon nitride layer 110) above interface 122. For instance, a recipe for step 212 may include a masking step (e.g., a lithography step to define the recessed gate region) and then selectively etching silicon nitride using a fluorine based plasma chemistry. A recipe for step 214 may include selectively etching the remaining AlGaN barrier layer 108 above the interface 122. The AlGaN barrier layer 108 above the interface 122 may be etched by using RIE with a chlorine based plasma chemistry. Accordingly, the transition from step 212 to step 214 may include switching from using a flourine based plasma to using a chlorine based plasma such as boron trichloride (BCL3).

The recipe for step 214 may further include over-etching the AlGaN barrier layer 108 to ensure complete removal of the AlGaN barrier layer. Accordingly, step 214 may include over-etching by more than a thickness d1 (i.e., thickness d1 of the AlGaN barrier layer 108) using the chlorine based plasma. For example, if thickness d1 is four nanometers to six nanometers, then step 214 may call for etching at least ten nanometers. According to the teachings herein, step 214 may be tailored to etch through the AlGaN barrier layer 108 using less reactive ion etching (RIE) power and reduced etch rate (e.g., a rate less than or equal to ten nanometers per minute). Advantageously, using less RIE power may mitigate etching/ion induced damage at the surface interface 122.

The next steps 216 and 208 may correspond with forming a dual dielectric gate stack (i.e., the dual dielectric 121). Step 216 may correspond with the deposition of aluminum nitride (AlN) to form the aluminum nitride layer 113 of thickness d4. For instance, the aluminum nitride may be deposited using an atomic layer deposition (ALD) process so as to create the interface 122 with the GaN active layer 106. Accordingly, the aluminum nitride layer 113 may be deposited with a thickness d4 between four nanometers and eight nanometers. The aluminum nitride layer 113 may advantageously reduce interface states at the interface 122 by ensuring continuous, non-dangling bonds. Step 218 may correspond with the subsequent deposition of aluminum oxide to form the aluminum oxide layer 114 of thickness d5 (e.g., five nanometers to fifteen nanometers). The aluminum oxide layer 114 may also be deposited using an ALD process in-situ by switching from nitrogen to oxygen precursor in step 218. The thickness d5 may be selected to ensure a threshold voltage (e.g., a gate-to-source threshold voltage) and to ensure a maximum gate voltage (e.g., five volts maximum).

Next, step 220 may correspond with forming the gate contact 116. As discussed above, the gate contact 116 may also be a metal alloy including, but not limited to aluminum and/or titanium. As one of ordinary skill in the art may appreciate, there may be additional process steps including those relating to lithography and subsequent steps relating to patterning additional passivation and/or metallization. For instance, there may be subsequent process steps to pattern and/or deposit field plates for high voltage operation.

FIG. 2B illustrates a process flow 220 for fabricating an enhancement mode metal insulator semiconductor HEMT according to a second embodiment. Step 222 may refer to forming a first active layer (e.g., a GaN active layer 106). The first active layer can be an epitaxial layer formed (e.g., grown) using MOCVD. According to the teachings herein, the next step 224 may refer to forming a polarization stack (e.g., polarization stack 115) suitable for low-power etching (e.g., reactive ion etching) and tailored for generating a low resistance two-dimensional electron gas (e.g., two-dimensional electron gas 109). Step 227 may refer to forming Ohmic contacts (e.g., source Ohmic contact 109S and drain Ohmic contact 109D). Step 228 may refer to forming a passivation layer (e.g., passivation layer 112) of thickness d3 (e.g., one hundred and fifty nanometers). The passivation layer 112 can comprise silicon nitride and may be formed by PECVD. Step 230 may refer to forming a recessed gate (e.g., a recessed gate region 123).

FIG. 2C illustrates a process flow for forming a polarization stack 115 according to an embodiment of step 224. Step 225 may refer to forming a second active layer (e.g., an AlGaN barrier layer 108) of thickness d1 on the first active layer. According to the teachings herein, the second active layer may be thinner than state of the art values (e.g., thinner than ten nanometers); and the second active layer can also be an epitaxial layer formed (e.g., grown) using MOCVD. For instance, in one embodiment the second active layer may be an AlGaN barrier layer 108 having a thickness d1 of four to six nanometers, which may lead to a high measured sheet resistance of greater than one-thousand Ohms-per-square.

Step 226 may refer to forming a first dielectric layer (e.g., a silicon nitride layer 110) of thickness d2 on the second active layer. Also, according to the teachings herein, the first dielectric layer may, in combination with the second active layer, form a polarization stack 115 suitable for generating a low sheet resistance two dimensional electron gas 109. In step 226 the first dielectric layer may be grown in-situ following step 225; alternatively, the first dielectric layer may be grown ex-situ. For instance, in one embodiment the first dielectric layer may be a silicon nitride layer 110 of thickness d2 substantially equal to forty nanometers. The first dielectric layer with the second active layer may give rise to piezoelectric polarization, thereby reducing the sheet resistance (i.e., the sheet resistance of a two dimensional electron gas 109) to be less than or substantially equal to six-hundred and fifty Ohms-per-square.

FIG. 2D illustrates a process flow for forming a recessed gate (e.g., a recessed gate region 123) according to an embodiment of step 230. Step 232 may refer to etching a gate via opening. In addition to masking steps and photolithography, step 232 may include using a reactive ion etching (RIE) process. For instance, when the passivation layer 112 and the first dielectric layer (e.g., silicon nitride layer 110) comprise silicon nitride, then step 232 may first refer to using a fluorine based plasma chemistry to etch through silicon nitride. Also, when the second active layer comprises AlGaN (e.g., the AlGaN barrier layer 108), then step 232 may further refer to switching from the fluorine based plasma chemistry to a chlorine based chemistry to etch and/or over-etch AlGaN. According to the teachings herein, the etching process (e.g., RIE process) for the thinner second active layer (e.g., the AlGaN barrier layer 108 of thickness d1) may advantageously allow for a reduced power (e.g., reduced etch rate). This, in turn, may reduce etching-induced surface damage of the first active layer (e.g., GaN active layer 106). Step 234 refers to depositing a dual dielectric, and according to the teachings herein, the dual dielectric can be deposited to ensure continuous non-dangling bonds at an interface (e.g., surface interface 122). Step 237 may refer to depositing a gate contact (e.g., gate contact 116).

FIG. 2E illustrates a process flow for depositing the dual dielectric according to an embodiment of step 234. Step 235 may correspond with depositing an aluminum nitride layer 113 of thickness d3 using atomic layer deposition (ALD). Step 236 may refer to subsequently depositing an aluminum nitride layer 114 of thickness d4 using ALD.

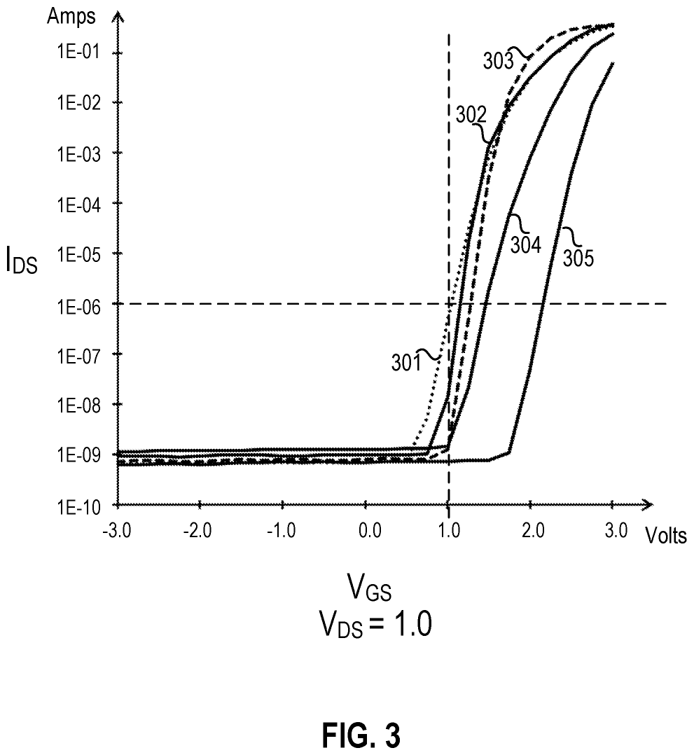

FIG. 3 illustrates transfer characteristics 301-305 of drain-to-source current I_{DS} versus gate-to-source voltage V_{GS} for a HEMT fabricated according to the teachings herein. The transfer characteristics 301-305 are measured on sample HEMTs at wafer locations corresponding to wafer center, wafer east, wafer north, wafer south, and wafer west, with respect to a wafer flat. Additionally, the measurements correspond with an applied drain-to-source voltage VDS of one volt; and the drain-to-source current I_{DS} is plotted on a logarithmic scale versus gate-to-source V_{GS} voltage from negative three volts to positive three volts.

As illustrated by each of the transfer characteristics 301-305, the sample HEMTs cells operate in enhancement mode with low leakage. For instance, when the gate-to-source voltage V_{GS} is zero, the drain-to-source current I_{DS} has an order of magnitude of nano-amperes (i.e., 1E-09 amps) or less. Additionally, a one micro-amperes threshold voltage, defined as the gate-to-source voltage V_{GS} measured when drain-to-source current I_{DS} equals to one micro-amperes (i.e., 1E-06 amps), is greater than one volt.

As presented herein, one aspect of the teachings is an enhancement mode semiconductor device (i.e., an enhancement mode metal insulator semiconductor HEMT). The enhancement mode semiconductor device comprises a first active layer (e.g., a GaN active layer 106), a gate stack (e.g., a dual dielectric 121), and a polarization stack (e.g., a polarization stack 115). The gate stack comprises an aluminum nitride (AlN) layer (e.g., aluminum nitride layer 113) disposed on the first active layer. The polarization stack comprises a second active layer (e.g., an AlGaN barrier layer 108) and a first dielectric layer (e.g., a silicon nitride layer 110). The second active layer has a thickness (e.g., a thickness d1) less than ten nanometers and is disposed on the first active layer. The first dielectric layer is disposed on the second active layer so as to effectuate a piezoelectric polarization. A two-dimensional electron gas (e.g., a two-dimensional electron gas 109) forms between the first active layer and the polarization stack in response to the piezoelectric polarization.

In another aspect a method of fabricating a semiconductor device comprises: forming a first active layer (e.g., a GaN active layer 106 per step 222) on a substrate (e.g., substrate 102); forming a polarization stack (e.g., a polarization stack 115 per step 224); forming Ohmic contacts (e.g., source and drain Ohmic contacts 109S, 109D per step 227) to the first active layer; depositing a passivation layer (e.g., passivation layer 112 per step 228); and forming a recessed gate (e.g., a recessed gate region 123 per step 230). The polarization stack is formed by forming a second active layer (e.g., an AlGaN barrier layer 108 per step 225) on the first active layer and by forming a first dielectric layer (e.g., a silicon nitride layer 110 per step 226) on the second active layer. The second active layer has a thickness less than ten nanometers (e.g., four to six nanometers); and the first dielectric layer is formed to effectuate a piezoelectric polarization. A two-dimensional electron gas is formed between the first active layer and the second active layer. The Ohmic contacts comprise a source Ohmic contact (e.g., source Ohmic contact 109S) and a drain Ohmic contact (e.g., drain Ohmic contact 109D). The recessed gate is formed by etching a gate via opening (e.g., step 232), depositing a dual dielectric (e.g., step 234), and depositing a gate contact (e.g., step 237). The gate via opening may be etched (e.g., over-etched) so as to expose the first active layer; and the dual dielectric may comprise aluminum nitride (AlN) (e.g., aluminum nitride layer 113).

The above description of illustrated examples of the present disclosure, including what is described in the Abstract, are not intended to be exhaustive or to be limitation to the precise forms disclosed. While specific embodiments of, and fabrication steps of an enhancement mode metal insulator semiconductor HEMT are described herein for illustrative purposes, various equivalent modifications are possible without departing from the broader spirit and scope of the present disclosure. Indeed, it is appreciated that the specific example process recipes and device cross sections are provided for explanation purposes and other process recipes with greater or fewer steps may also be employed in other embodiments and examples in accordance with the teachings herein.

What is claimed is:

1. An enhancement mode semiconductor device comprising:
a first active layer;
a gate stack comprising:
an aluminum nitride layer disposed on the first active layer;
a polarization stack comprising:
a second active layer having a thickness of less than ten nanometers and disposed on the first active layer; and
a first dielectric layer disposed on the second active layer so as to effectuate a piezoelectric polarization, wherein a two-dimensional electron gas forms between the first active layer and the polarization stack in response to the piezoelectric polarization.

2. The enhancement mode semiconductor device of claim 1, wherein the thickness is between four nanometers and six nanometers.

3. The enhancement mode semiconductor device of claim 1, wherein the first active layer comprises gallium nitride (GaN).

4. The enhancement mode semiconductor device of claim 1, wherein the second active layer comprises aluminum gallium nitride (AlGaN).

5. The enhancement mode semiconductor device of claim 1, wherein the first dielectric layer comprises silicon nitride.

6. The enhancement mode semiconductor device of claim 1, comprising:
a passivation layer disposed on the first dielectric layer.

7. The enhancement mode semiconductor device of claim 6, wherein the passivation layer comprises silicon nitride.

8. The enhancement mode semiconductor device of claim 1, comprising:
a source comprising a source metal layer electrically connected to the two dimensional electron gas via a source Ohmic contact; and
a drain comprising a drain metal layer electrically connected to the two dimensional electron gas via a drain Ohmic contact.

9. The enhancement mode semiconductor device of claim 8, wherein the gate stack comprises:
an aluminum oxide layer disposed on the aluminum nitride layer.

10. The enhancement mode semiconductor device of claim 9, comprising:
a gate comprising a gate electrode formed above the aluminum oxide layer between the source and the drain.

11. The enhancement mode semiconductor device of claim 10, wherein the gate is recessed between the source and the drain.

12. A method of fabricating a semiconductor device comprising:
forming a first active layer on a substrate;
forming a polarization stack comprising:
forming a second active layer on the first active layer, the second active layer having a thickness less than ten nanometers;
forming a first dielectric layer on the second active layer to effectuate a piezoelectric polarization whereby a two-dimensional electron gas is formed between the first active layer and the second active layer;
forming Ohmic contacts, the Ohmic contacts comprising a source Ohmic contact and a drain Ohmic contact;
depositing a passivation layer; and
forming a recessed gate comprising:
etching a gate via opening so as to expose the first active layer;
depositing a dual dielectric comprising aluminum nitride; and
depositing a gate contact.

13. The method of claim 12, wherein depositing a passivation layer comprises:
depositing a silicon nitride passivation layer.

14. The method of claim 13, wherein forming the first active layer on the substrate comprises:
forming a gallium nitride buffer layer;
forming the first active layer on the gallium nitride buffer layer, the first active layer comprising gallium nitride (GaN).

15. The method of claim 14, wherein forming the second active layer on the first active layer comprises:
growing the second active layer, the second active layer comprising aluminum gallium nitride (AlGaN).

16. The method of claim 15, wherein the second active layer has a thickness between four and six nanometers.

17. The method of claim 15, wherein forming the first dielectric layer on the second active layer comprises:
growing the first dielectric layer in-situ with the second active layer, the first dielectric layer comprising silicon nitride.

18. The method of claim 17, wherein growing the polarization stack comprises:
growing the first dielectric layer in-situ with the second active layer to effectuate the piezoelectric polarization, whereby a sheet resistance due to the two-dimensional electron gas is less than or equal to six-hundred Ohms-per-square.

19. The method of claim 17, wherein forming the first dielectric layer on the second active layer comprises:
growing the first dielectric layer ex-situ with the second active layer, the first dielectric layer comprising silicon nitride.

20. The method of claim 17, wherein etching the gate via opening comprises:
selectively etching silicon nitride with a fluorine based plasma; and
subsequently etching AlGaN with a chlorine based plasma.

21. The method of claim 20, wherein etching AlGaN with the chlorine based plasma comprises:
etching at a rate equal to or less than ten nanometers per minute.

22. The method of claim 20, wherein etching AlGaN with the chlorine based plasma comprises:
over etching the second active layer so as to expose the first active layer.

23. The method of claim 22, wherein depositing the dual dielectric comprises:
depositing an aluminum nitride layer using atomic layer deposition, the aluminum nitride layer deposited on the first active layer to bond a GaN surface with the aluminum nitride layer.

24. The method of claim 23, wherein depositing the dual dielectric comprises:
subsequently depositing an aluminum oxide layer on the aluminum nitride layer.
